(19) United States
(12) Patent Application Publication
(10) Pub. No.: US 2012/0273029 A1
(43) Pub. Date: Nov. 1, 2012

(54) SOLAR ARRAY

(75) Inventors: Elio Bragagna, Duens (AT); Lukas Mundwiler, Gams (CH)

(73) Assignee: Hilti Aktiengesellschaft, Schaan (LI)

(21) Appl. No.: 13/409,373

(22) Filed: Mar. 1, 2012

(30) Foreign Application Priority Data
Apr. 26, 2011 (DE) DE 102011017518.0

(51) Int. Cl. H01L 31/048; E04D 13/18; F24J 2/52

(52) U.S. Cl. 136/251; 126/704; 126/621

(57) ABSTRACT

A self-supporting solar array includes a plurality of solar modules and a substructure that supports the solar modules and connects them to each other. The substructure defines a plurality of module positions at each of which a solar module is arranged. Module positions configured as S-module positions are provided in the substructure, and they each have a wind deflector that covers up a passage opening leading to the bottom of the solar module arranged in each S-module position. Aside from the S-module positions, the substructure also has module positions configured as F-module positions in which at least part of the passage opening is free, whereas it is covered by the wind deflector in the case of an S-module position.

This claims the benefit of German Patent Application DE 10 2011 017518.0 dated Apr. 26, 2011 and hereby incorporated by reference herein.

The invention relates to a self-supporting solar array. Such a solar array is configured with a plurality of solar modules and a substructure that supports the solar modules and connects them to each other, whereby the substructure defines a plurality of module positions at each of which a solar module is arranged, whereby module positions configured as S-module positions are provided in the substructure, and they each have a wind deflector that covers up a passage opening leading to the bottom of the solar module arranged in each S-module position.

### BACKGROUND

U.S. Pat. Appl. No. 2009/242014 A, for instance, discloses self-supporting fastening structures for solar modules that allow solar modules to be mounted at an angle with respect to the horizontal and in rows on flat roofs, without the need to create a direct attachment or connection to the building. Ballast is used to prevent the attachment structure from shifting or being lifted up.

### SUMMARY OF THE INVENTION

Since, in most cases, the load-bearing capacity of roofs is limited, it can be necessary to take measures to reduce the amount of ballast. For instance, U.S. Pat. Appl. No. 2009/242014 A and international patent application WO 07/079382 A2 disclose the approach of providing each solar module with a wind deflector in the form of a metal sheet that is installed on the north side of the slanted module, in other words, on the edge where the slanted module is at the furthest distance from the roof surface. This measure takes into account the fact that, as a rule, the strongest wind forces act on a partially raised slanted module when the wind strikes the structure blowing from the north, thus striking the bottom of the slanted module. A wind deflector in the form of a metal sheet that is installed on the north side of the module can divert the wind around the module, thereby greatly reducing the lifting force. Under certain circumstances, it is even possible to make do without any ballast whatsoever.

It is an objective of the present invention to provide a particularly cost-effective and lightweight self-supporting solar array that, at the same time, is also very easy to mount.

A solar array according to the invention is characterized in that, aside from the S-module positions, the substructure also has module positions configured as F-module positions in which at least part of the passage opening is free, whereas it is covered by the wind deflector in the case of an S-module position. Accordingly, the substructure according to the invention defines S-module positions as well as F-module positions. In particular, it can be provided that all of the module positions are either S-module positions or F-module positions, in other words, that no other types of module positions are present. In the case of the F-module positions, at least part of the passage opening is free, whereas it is covered by the wind deflector in the case of an S-module position, that is to say, uncovered, thus allowing a passage to the atmosphere. In particular, the wind deflector can be completely absent in the case of F-module positions.

The invention is based on the findings acquired from in-depth wind-tunnel experiments, which have revealed that the wind often does not act on all parts of the solar array with the same intensity. Rather, there are frequently exposed parts of the solar array where the wind loads are greater on the average, and places that are less exposed, where the wind loads are smaller on the average. For instance, it was observed that higher forces often occur at the edge zones of a solar array than in the interior of the solar array. This observation, which can be referred to as a “slipstream effect” is due to the fact that the wind strikes the modules in the edge area of the array at full-force, whereas the modules that are situated behind the edge modules are in the slipstream of the edge modules so to speak, so that, on the average, lesser lifting forces act upon these modules.

Furthermore, the invention is based on the recognition that a rigid substructure is such that the wind loads that occur locally on the individual modules can be distributed over the entire solar array. Therefore, if certain module positions are provided with a wind deflector that generates downward forces when wind loads occur, then these downward forces can also be transmitted via a rigid substructure to the adjacent module positions, where it applies a downward force, even if no wind deflectors are present there.

With these findings as the starting point, the invention now provides a wind deflector for only some of the module positions, the so-called S-module positions, and systematically configures the rest of the module positions, the so-called F-module positions, without wind deflectors, at least some of them but especially all of them. In particular, according to the invention, the wind deflectors can be systematically arranged where, on the average, the wind exerts the greatest lifting forces and/or where, on the average, the wind deflectors generate relatively large downward forces when exposed to wind. In contrast, the remaining module positions, especially those in the slipstream, on which the wind has only a slight effect on the average, can be configured according to the invention as so-called F-module positions, which are free of wind deflectors. Since, according to the invention, the wind deflector is absent in at least some of the module positions, in comparison to an array from the state of the art, which is completely equipped with wind deflectors, the invention accounts for cost efficiency and a particularly low weight, which is advantageous in terms of the load-bearing capacity of the roofs. Moreover, F-module positions, which are free of wind deflectors, allow a very good ventilation and thus cooling of the modules in question, thus translating into very high rates of efficiency.

These solar modules can especially be photovoltaic modules. Fundamentally speaking, the solar modules can also be solar-thermal solar modules.

Advantageously, the substructure has numerous feet that each support and/or connect four adjacent solar modules to each other. As a result, a particularly cost-effective substructure can be obtained that, at the same time, is very stiff, thus ensuring very good force transmission between the F-module positions and the S-module positions. In particular, it can be provided that the substructure has numerous feet, whereby each of the feet holds four module corners, whereby the four module corners belong to four different solar modules. The solar modules are advantageously firmly clamped onto the feet, for which purpose suitable module clamps can be provided. Edge feet having different configurations such as, for instance, feet that only support two solar modules or only one solar module, can also be provided in the edge areas of the solar array according to the invention.

According to another advantageous variant, it is provided that the feet are cast parts. In particular, the feet can be cast metal parts, for example, cast aluminum parts, preferably die-cast aluminum parts. The use of a cast material translates into very high stiffness in the substructure, which can ensure a very good distribution of the wind loads and thus potentially can render the use of numerous wind deflectors superfluous. The advantage of this variant becomes especially evident in comparison to a concept with feet that are made of relatively flexible bent metal parts, whereby the wind deflectors are used in order to impart the structure with the necessary stability. Even though this comparative concept reduces the costs of the substructure, this comparative concept requires the installation of wind deflectors at all of the module positions in order to ensure the requisite stability. Here, the wind deflectors have an aerodynamic function as well as a static function in the sense of providing a reinforcement. The wind deflectors account for the lion's share of the costs of this comparative concept and these costs are relatively high in comparison to approaches without wind deflectors. In contrast to this approach, the invention calls for uncoupling the static and aerodynamic functions, so that snow and wind loads can be absorbed by the substructure, even without wind deflectors. This uncoupling of the static and aerodynamic functions makes it possible to use wind deflectors only in some areas of the array, thus reducing the total costs.

Especially in order to achieve further reinforcement and thus to achieve a better distribution of wind loads, it is advantageous for adjacent feet to be joined by struts, at least in part of the substructure. In a practical manner, adjacent feet are joined by struts in at least one spatial direction, especially in two spatial directions.

As a rule, the more module positions the solar array has, the more noticeable the above-mentioned slipstream effect and thus the advantageous effect of the invention are. Accordingly, the invention lends itself especially well for use in large solar arrays. Consequently, it is particularly advantageous for at least 25 module positions, at least 50 module positions or at least 100 module positions, to be provided.

Very good savings in terms of weight can be obtained when more than 25%, more than 50% or more than 75% of the module positions are F-module positions. Preferably, at least 10%, at least 20% or at least 30% of the module positions are S-module positions, that is to say, module positions with wind deflectors.

It is likewise preferred for at least some of the module positions to be arranged in a rectangular matrix when the solar array is seen from above. This even further facilitates the mounting work. Since, as mentioned above, the more module positions the solar array has, the more evident the advantageous effect of the invention generally is; the matrix advantageously has at least five rows and at least five columns.

Another advantageous embodiment of the invention is that, when the solar array is seen from above, precisely one contiguous F-area consisting of F-module positions is formed, whereby the contiguous F-area contains at least 70%, at least 80% or at least 90% of all of the F-module positions of the solar array, that is to say, essentially all of the F-module positions of the solar array. This embodiment takes into account the fact that the slipstream effect has a relatively large range. As a result, the F-module positions can be concentrated in one area of the solar array which, in turn, facilitates the mounting work, since such a concentration in one area allows the creation of very simple mounting patterns.

Moreover, it is advantageous for at least 50%, at least 60% or at least 70% of the edge module positions that are at the edge of the solar array, as seen from above, to be S-module positions. This embodiment takes into consideration that the above-mentioned slipstream effect is only noticeable in the module positions that are on the inside, whereas the edge module positions are often exposed to the wind without any protection. For this reason, this embodiment provides for a considerable number of the edge positions to be configured with wind deflectors so that, on the one hand, a high level of protection against the wind is attained and, on the other hand, a very pronounced slipstream effect, is achieved.

Another advantageous refinement of the invention lies in the fact that at least 70%, at least 80% or at least 90% of the S-module positions, in other words, essentially all of the S-module positions, are arranged in a U-shaped pattern when the solar array is seen from above. This embodiment takes into account that, first of all, solar arrays, especially with slanted modules, generally do not have an isotropic structure and thus respond differently to wind coming from different directions and, secondly, it can also take into consideration the fact that there are often prevalent weather conditions and thus prevalent wind directions at the mounting location. Thanks to the arrangement of the module positions having the wind deflectors in a U-shaped pattern, it is possible to systematically protect the edges of the solar array that are more susceptible to the wind, so that very good properties can be attained as far as the wind is concerned, while the weight is also kept low.

According to the invention, the solar array can have a north side, a south side, an east side and a west side. In accordance with the convention that normally applies in solar technology, these directions do not relate primarily to the orientation of the solar array relative to the poles of the earth, but rather, to the inclination of the solar modules relative to the horizontal. Accordingly, the south side is the side toward which the photoactive tops of the solar modules are slanted, while the other sides are arranged according to a compass rose. In the Northern hemisphere, such a solar array will usually have the greatest effect if the south side of the solar array is oriented towards the geographical south.

The aerodynamic experiments conducted with solar arrays on roofs within the scope of the invention have demonstrated that wind deflectors often work most efficiently when they are on the east, north and west sides of the photovoltaic installation. Accordingly, it is advantageous for both side legs of the above-mentioned U-shaped pattern of the S-module positions to run in the north-south direction and for the center leg to run in the east-west direction.

Furthermore, it was ascertained within the scope of the experiments that the remaining load-bearing capacity of the roof can have an influence on the arrangement of the wind deflectors. In order to attain the best possible balance between additional costs and aerodynamic efficiency, the arrangement of wind deflectors can be adapted to the remaining load-bearing capacity. As a result, there is a variation in the advantageous number of S-module rows on the north side and in the advantageous number of S-module columns on the east and west sides of the solar array. Advantageously, starting from the north side, there are one to six rows of modules, and/or starting from the east side and the west side, there are one to six columns of the matrix as S-module positions with wind deflectors.

In another preferred embodiment, in at least one corner of the matrix, there is a corner protection area where the surface density of the S-module positions is greater than in the vicinity of the corner protection area. In particular, such a corner protection area can be provided at the northwestern corner and/or at the northeastern corner. This embodiment takes into consideration the fact that turbulences in the corner areas can have an effect further into the center of the solar array than on the sides. For this reason, according to the preferred embodiment, corner protection areas are created in the area of these corners, where relatively numerous wind deflectors are present in such areas in comparison to the vicinity of the corner protection areas, so that the surface density of the wind deflectors, in other words, the surface density of the S-module positions, is higher there, at least locally. Such corner protection areas are particularly advantageous in those cases when only relatively few rows and columns are equipped with wind deflectors.

Advantageously, the invention is deployed in a ready-to-use and completely mounted solar array. Accordingly, it is particularly advantageous for the solar array to be arranged on a roof. The substructure, which can also be referred to as the fastening structure, thus advantageously constitutes a roof mount to which the solar modules can be fastened, preferably at an angle. Moreover, the invention also relates to the operation of a solar array which, according to the invention, has S-module positions as well as F-module positions, and also to the use of a solar array according to the invention for converting sunlight into electric energy which is then fed to a power supply network.

### BRIEF DESCRIPTION OF THE DRAWINGS

The invention will be explained in greater detail below on the basis of preferred embodiments that are schematically shown in the accompanying figures. The figures schematically show the following:

FIG. 1—a top view of a first embodiment of a solar array according to the invention;

FIG. 2—a top view of a second embodiment of a solar array according to the invention; and

FIG. 3—a perspective detailed sectional view of the solar array from FIG. 1 or FIG. 2.

### DETAILED DESCRIPTION

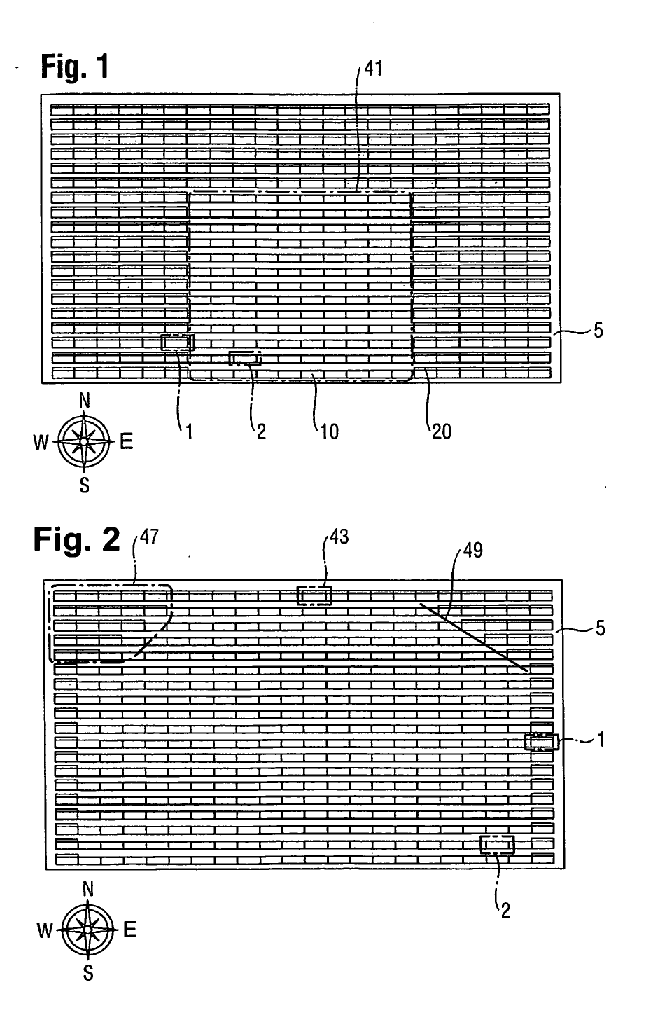

A first embodiment of a solar array according to the invention is depicted in FIG. 1. As is shown in FIG. 1, the solar array has a plurality of module positions 1 and 2 on each of which a solar module 10 is arranged. The module positions 1 and 2 are arranged in the form of a rectangular matrix, in the case of FIG. 1, for example, with 22 columns running in the north-south direction (N-S) and nineteen rows running in the east-west direction (E-W).

As is also shown in FIG. 1, in some of the module positions, namely, the so-called S-module positions, a wind deflector 20 is associated with the solar modules 10 that are in the module positions 1.

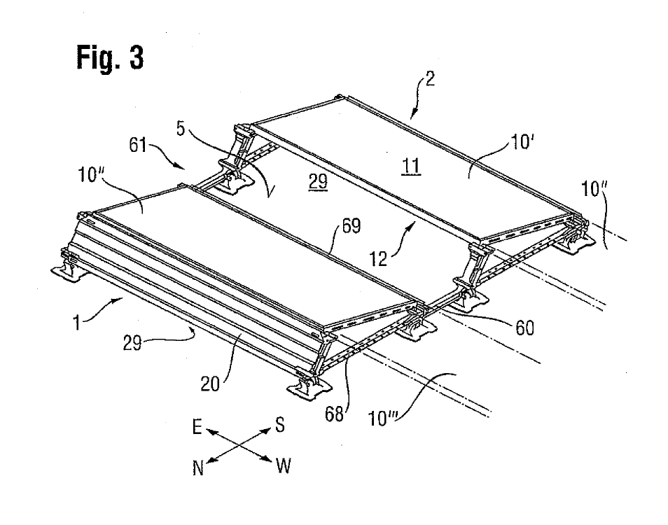

Details of the solar array from FIG. 1 are depicted in FIG. 3, which shows a section of the array from FIG. 1. As can be seen in FIG. 3, the solar array has a substructure 61 with numerous feet 60 that stand on a roof 5 and that raise the solar modules 10. As is shown in FIG. 3, on the basis of the example of the feet provided with the reference numeral 60, each foot supports four adjacent solar modules 10, in the example the solar modules 10′, 10″, as well as the solar modules 10′″ and 10″″, which are merely indicated by broken lines. The feet 60 are inner feet; at the edge of the solar array, there can also be differently configured feet that each support only two solar modules 10 or only one solar module 10. Module clamps, for instance, can be provided for purposes of attaching the solar module 10 to the feet 60.

The solar modules 10 each have a photoactive top 11 as well as an opposite bottom 12. The solar modules 10 are held by the substructure 61 at an angle to the horizontal and/or to the surface of the roof 5, whereby, in accordance with the convention that normally applies in solar technology, the direction towards which the photoactive top 11 of the solar module 10 is tilted is the south direction (S) of the array. The other directions (N), west (W) and east (E) are arranged according to a conventional compass rose.

FIG. 3 gives a detailed view by way of an example of an F-module position 2, namely, on the solar module 10′, and an S-module position 1, namely, on the solar module 10″. No wind deflector is provided for the solar module 10′ at the F-module position 2. In this manner, there is a passage opening 29 on the north side of the solar module 10′ of the F-module position 2 leading to the bottom 12 of the solar module 10′. For the S-module position 1, in contrast, a wind deflector 20 is provided for the solar module 10″ and arranged on the north side of the solar module 10″, from where it runs downwards at an angle to the horizontal. This wind deflector 20 covers the passage opening 29 of the S-module position 1.

As can also be gleaned from FIG. 3, the individual feet 60 are joined by struts 68 in the north-south direction and by struts 69 in the east-west direction, thus accounting for a high level of stiffness.

In the embodiment shown in FIG. 1, all of the S-module positions 1 are arranged in a U-shaped pattern that is open towards the south side. The F-module positions 2 are arranged in a single, contiguous F-area 41 which is rectangular in the embodiment of FIG. 1. In the embodiment of FIG. 1, the S-module positions 1 extend from the western edge, from the northern edge and from the eastern edge of the matrix-shaped array by six positions into the interior of the array.

Another embodiment of the solar array according to the invention is depicted in FIG. 2, whereby, like in FIG. 1, the viewing direction in FIG. 2 is a top view of the roof 5, and whereby the detailed view of FIG. 3 can also be related to the embodiment of FIG. 2.

Similar to the embodiment of FIG. 1, also in the case of the embodiment of FIG. 2, all of the S-module positions 1 are arranged in a U-shaped pattern that is open towards the south side, and the F-module positions 2 are arranged in a single, contiguous F-area that here, for the sake of clarity, is not provided with a reference numeral.

In the embodiment of FIG. 2, all of the edge module positions 43 that are arranged on the western edge, on the northern edge and on the eastern edge are configured as S-module positions 1. In contrast to the embodiment of FIG. 1, the S-module positions according to FIG. 2, however, do not extend as far into the interior.

Since the corners of the array are frequently exposed to considerable wind loads, in the embodiment of FIG. 2, the northwestern corner and the northeastern corner are provided with a corner protection area 47 where the surface density of the S-module positions 1 with the wind deflector 20 is greater in comparison to the vicinity. At the corner protection areas 47, the boundary line 49 between the S-module positions 1 and the F-module positions 2 forms a bevel that runs at an angle to the edges of the array, especially at an angle of 45°. The boundary line 49 can run, for example, also along a convex or a concave course.

What is claimed is:

1. A self-supporting solar array, comprising:
a plurality of solar modules; and
a substructure supporting the solar modules and connecting the solar modules to each other, the substructure defining a plurality of module positions, a solar module being arranged at each of the module positions and having a passage opening leading to an underside of the solar module, module positions configured as S-module positions being provided in the substructure, each S-module position having a wind deflector covering up the passage opening of the solar module arranged in each S-module position, and the substructure also having module positions configured as F-module positions, at least part of the passage opening of the solar module being free in the F-module positions.

2. The solar array as recited in claim 1 wherein the substructure has a plurality of feet each supporting or connecting four adjacent solar modules to each other, the feet being cast parts.

3. The solar array as recited in claim 2 wherein the cast parts are die-cast aluminum parts.

4. The solar array as recited in claim 2 further comprising struts joining adjacent feet at least in part of the substructure.

5. The solar array as recited in claim 1 wherein at least 25 module positions are provided, and more than 25% of the module positions are F-module positions.

6. The solar array as recited in claim 1 wherein at least some of the module positions are arranged in a rectangular matrix when the solar array is seen from above.

7. The solar array as recited in claim 1 wherein, when the solar array is seen from above, precisely one contiguous F-area of F-module positions is formed, the contiguous F-area containing at least 80% of all of the F-module positions of the solar array.

8. The solar array as recited in claim 1 wherein at least 50% of the edge module positions at an edge of the solar array, as seen from above, are S-module positions.

9. The solar array as recited in claim 1 wherein at least 80% of the S-module positions are arranged in a U-shaped pattern when the solar array is seen from above.

10. The solar array as recited in claim 6 wherein, in at least one corner of the matrix, a corner protection area is present where a surface density of the S-module positions is greater than in a vicinity of the corner protection area.

11. The solar array as recited in claim 1 wherein the solar array is arranged on a roof.

12. A method for the solar array as recited in claim 1 comprising:
converting sunlight into electric energy using the solar array; and
then feeding the electric energy to a power supply network.
